(19) United States
(12) Patent Application Publication
(10) Pub. No.: US 2024/0124776 A1
(43) Pub. Date: Apr. 18, 2024

(54) HIGH PERFORMANCE SEMICONDUCTOR GRADE DIMETHYLALUMINUM CHLORIDE

(71) Applicants: Laurence E. Spurgeon, Rio Rancho, NM (US); Ashwini K. Sinha, East Amherst, NY (US); Douglas C. Heiderman, Akron, NY (US); Stanley M. Smith, Clarence Center, NY (US); Oleg Byl, Williamsville, NY (US)

(72) Inventors: Laurence E. Spurgeon, Rio Rancho, NM (US); Ashwini K. Sinha, East Amherst, NY (US); Douglas C. Heiderman, Akron, NY (US); Stanley M. Smith, Clarence Center, NY (US); Oleg Byl, Williamsville, NY (US)

(21) Appl. No.: 18/333,838

(22) Filed: Jun. 13, 2023

Related U.S. Application Data
(60) Provisional application No. 63/416,053, filed on Oct. 14, 2022.

(51) Int. Cl. C09K 13/00; C07F 5/06; F17C 5/06; H01L 21/265; H01L 21/3065

(52) U.S. Cl. CPC C09K 13/00; C07F 5/064; F17C 5/06; H01L 21/265; H01L 21/3065

(57) ABSTRACT

Novel high purity dimethylaluminium chloride compositions are provided that are suitable for semiconductor applications, such as atomic layer etch and aluminum ion implantation. The reduction or minimization of specified gaseous impurities allows the vapor phase of the DMAC to have purity levels of 99.9 mol % or higher to selectively etch various atomic layers with high selectivity and high etch precision at acceptable etch rates and 99 mol % or higher to ion implant aluminum ions without substantial implantation of C2H3 ions into a wafer device, thereby avoiding degradation or failure of the wafer device. Storage conditions are established that are conducive to maintaining the high purity levels required for such semiconductor applications.

### RELATED APPLICATIONS

This application claims the benefit of priority from U.S. Serial Application No. 63/416,053 filed on Oct. 14, 2022, which is incorporated herein by reference in its entirety.

### FIELD OF THE INVENTION

This invention relates to novel, high purity dimethylaluminum chloride materials that are suitable for use in semiconductor grade applications, such as atomic layer etch and ion implantation. More particularly, the invention relates to high purity dimethylaluminum chloride at a purity level of 99.9 mol % or higher, with a balance of specifically identified combination of gaseous impurities maintained at or below their respective upper concentration limits to ensure superior etchant performance that is not adversely impacted by the presence of any of the gaseous impurities. Still further, the invention relates to high purity dimethylaluminum chloride at a purity level of 99 mol % or higher to ion implant aluminum ions without the substantial presence of C2H3 ions.

### BACKGROUND OF THE INVENTION

Atomic layer etching (ALE) is utilized as part of a promising new technology for advanced node fabrication of semiconductor devices. ALE is a process for thin film removal based on sequential, self-limiting surface reactions. The thin film is a layer of material that is previously deposited onto a substrate typically by atomic layer deposition (ALD). The thickness of the thin film that is removed by ALE ranges from fractions of a nanometer (i.e., monolayer) to several micrometers. ALE needs to remove the thin film with atomic layer control and precision. The ALE process is based on two steps. The first step is surface modification of the substrate or wafer through a reaction with a first gas, such as HF to produce a modified surface. The purpose of the modification step is to chemically modify a layer of the etched surface for a reaction with a second gas in the second step. In the case of HF utilized as the first gas, the modification reaction results in formation of a fluorinated layer on the surface and produces water that is removed as a vapor at the condition of the first reaction. The unmodified surface either does not react with a second gas or its reaction rate is too slow for practical purposes. The second step is removal of the modified surface by use of the second gas. The second gas can be any suitable etchant, including dimethylaluminium chloride (DMAC). In the case of the fluorinated surface and DMAC, the removal reaction involves halogen exchange when chlorine atoms from DMAC molecules are replaced with fluorine atoms from the modified surface producing dimethylaluminum fluoride and metal chloride, both volatile at the conditions of the second reaction. The second reaction self-terminates upon exhaustion of the fluorine atoms from the surface, leaving behind the pristine surface ready for the next ALE cycle. A generalized overview of the ALE process with use of various etchants, including low grade DMAC, are provided in U.S. Pat. No. 10,381,227 to George et al., the details of which are incorporated herein by reference in its entirety for all purposes.

Additionally, there is an increasing need for aluminum (Al) implants to dope various semiconductor substrates. Aluminum ion (Al) implantation is gaining interest in integrated circuit (IC) manufacturing. DMAC source material is typically utilized in the industry to perform Al ion implantation. However, process challenges currently exist for effective implantation of Al ions. It has been widely observed in the industry that C2H3 ionic fragments are contained in the plasma during the Al ion implantation process. By virtue of a substantially identical atomic mass to that of Al, the C2H3 can inadvertently cross-contaminate part of the Al-based ion beam and potentially result in undesirable carbon cross-contamination with the ionized DMAC in the plasma. The C2H3 has an identical atomic mass as the Al ions, thereby making removal of the C2H3 impurities difficult by a mass analyzing magnet, which is intended to function by deflecting ions from the Al-based ion beam at varying trajectories according to its mass (e.g., mass-to-charge ratio). Ions of undesired mass are deflected away from the path of the Al-based ion beam. However, as a result of the identical atomic mass of the C2H3 impurities and the Al ions, the mass analyzing magnet is unable to deflect or remove the undesired C2H3 impurities from the Al ions. The adverse result is that the C2H3 impurities are implanted with the Al ions.

Numerous solutions have been proposed to minimize cross-contamination of C2H3 with an aluminum ion implant. By way of example, one solution to reduce the presence of such C2H3 is disclosed in U.S. Patent Publication No. 2022/0139644. US Patent Publication No. 2022/0139644 introduces fluorine molecules into the ion chamber in the form of a co-flow gas. Many different sources and/or mixtures of the fluorine and fluorine-containing compounds are proposed with a design objective to increase the mass of the C2H3 contaminant to a mass sufficiently greater than mass 27, thereby allowing its removal from the Al-based ion beam by the mass analyzing magnet.

Another technique for Al ion implantation utilizes solid aluminum salts as a source material that is heated in a vaporizer to produce a sufficient vapor pressure of the Al that can subsequently be supplied to an ion chamber. However, one of the drawbacks of utilizing solid aluminum salts is that the implant process is unacceptably slow and requires additional equipment such as a solid source vaporizer connected to the ion chamber.

In yet another process, pure aluminum metal or aluminum oxide target positioned inside an ion source is sputtered using a plasma. The plasma creates Al ions. However, the process is susceptible to contamination of the ion chamber with aluminum deposits which requires frequent chamber cleanings. Still further, the process exhibits a short filament life.

There continues to be a need to identify etchants with improved performance in terms of their ability to selectively etch certain atomic layers of materials over others. The need for selective etching and higher atomic precision for ALE is increasing to effectively meet the ever increasing semiconductor industry demand for miniaturization of wafer devices. There also continues to be a need to effectively implant aluminum ions without C2H3 ion cross-contamination.

### SUMMARY OF THE INVENTION

In a first aspect of the present invention, a high purity dimethylaluminum chloride (DMAC) composition suitable for use as a high precision, atomic layer etchant (ALE) in a semiconductor fabrication process, said composition, comprising: said high purity DMAC composition maintained under storage conditions in a liquid phase that is in substantial equilibrium with a high purity, vapor phase; the high purity, vapor phase having a purity level of about 99.9 mol % or greater of the DMAC, based on total moles in the vapor phase wherein the total moles in the vapor phase excludes an optional blanket gas that may occupy said vapor phase, and further wherein a balance of the total moles in the vapor phase is occupied by gaseous impurities; said gaseous impurities, comprising (i) atmospheric gases selected from the group consisting of H2, O2, N2, Ar, CO2, CO and any combination thereof; (ii) hydrocarbons of a general formula represented by CxHy where x and y are greater than 0 and can have any integer value; (iii) moisture, H2O; (iv) volatile hydrides; (v) chloride derivatives of the volatile hydrides; (vi) volatile chlorides; (vii) oxy-chlorides of the volatile hydrides; (viii) alkyl-aluminum compounds and corresponding chlorine derivatives thereof; wherein each of said gaseous impurities is contained in an amount greater than 0 mol % and up to about 0.1 mol % with the proviso that an aggregate amount of all of the gaseous impurities is no greater than about 0.1 mol %.

In a second aspect of the present invention, a high purity dimethylaluminum chloride (DMAC) composition suitable for use as a high precision, atomic layer etchant (ALE) in a semiconductor fabrication process, said composition, comprising: said high purity DMAC composition maintained under storage conditions with a vapor phase that is in substantial equilibrium with a liquid phase; the liquid phase having impurities; said impurities contained in the liquid phase comprising (i) hydrocarbons of a general formula represented by CxHy where x and y are greater than 0 and can have any integer value; (ii) moisture, H2O; (iii) metals in an amount greater than 0 mol % and up to about 0.01 mol %; (iv) hydrides comprising at least one of SixHy, GexHy, NH3, PH3, AsH3 and SbH3 where x and y are greater than 0 and can have any integer value; (v) chloride derivatives of the volatile hydrides; (vi) chlorides; (vii) oxychlorides of the chlorides; and (viii) alkyl-aluminum compounds and corresponding chlorine derivatives thereof; wherein each of said impurities in the liquid phase is contained in an amount greater than 0 mol % and up to about 0.1 mol % with the proviso that an aggregate amount of all of the liquid phase impurities is no greater than about 0.1 mol %.

In a third aspect, a high purity semiconductor grade DMAC composition maintained under storage conditions in a liquid phase that is in substantial equilibrium with a high purity vapor phase, whereby said high purity vapor phase of the high purity DMAC composition is configured for use as an atomic layer etchant with an etch selectivity ratio of species x to species y of about 10:1 or higher in a semiconductor fabrication process that uses HF as a first etchant gas followed by the high purity vapor phase of the high purity DMAC composition as the second etchant gas.

In a fourth aspect, a semiconductor grade dimethylaluminum chloride (DMAC) material stored in a substantially hermetically sealed and passivated canister, said DMAC material comprising a liquid phase in substantial equilibrium with a vapor phase occupying a predetermined headspace of the canister, said substantially hermetically sealed and passivated canister configured to maintain the vapor phase at a semiconductor grade purity level of 99.9 mol % or higher based on total moles in the predetermined headspace during transport, storage and use of the substantially hermetically sealed and passivated canister, wherein said total moles in the predetermined headspace excludes an optional blanket gas that may occupy said vapor phase.

In a fifth aspect, a high purity dimethylaluminum chloride (DMAC) composition suitable for use as a high precision, atomic layer etchant (ALE) in a semiconductor fabrication process, said composition, comprising: a substantially hermetically sealed and passivated canister; said high purity DMAC composition maintained in the substantially hermetically sealed and passivated canister under storage conditions in a liquid phase that is in substantial equilibrium with a high purity, vapor phase; the high purity, vapor phase having a purity level of about 99.9 mol % or greater of the DMAC, based on total moles in the vapor phase, wherein the total moles in the vapor phase excludes an optional blanket gas that may occupy said vapor phase, and further with a balance of the total moles in the vapor phase occupied by gaseous impurities; said gaseous impurities occupying a headspace of a predetermined volume in the substantially hermetically sealed and passivated canister, said gaseous impurities comprising at least one of (i) atmospheric gases selected from the group consisting of H2, O2, N2, Ar, CO2, CO and any combination thereof; (ii) hydrocarbons comprising at least one of SixHy, GexHy, NH3, PH3, AsH3 and SbH3; (iii) moisture, H2O; (iv) volatile hydrides comprising at least one of SixHy, GexHy, NH3, PH3, AsH3 and SbH3; (v) chloride derivatives of the volatile hydrides wherein said chloride derivatives comprise at least one of SixHyClz and GexHyClz, where x, y and z are greater than 0 and can have any integer value; (vi) volatile chlorides comprising at least one of C12, HCl, CCl4, SiCl4 and TiCl4; (vii) oxy-chlorides of the volatile chlorides comprising at least one of COCl2, MoO2Cl2 and SOCl2; (viii) alkyl-aluminum compounds and corresponding chlorine derivatives thereof comprising at least one of Al(CH3)3, CH3AlCl2 and (C2H5)xAlCly where x and y are greater than 0 and can have any integer value; whereby an aggregate amount of the gaseous impurities is 0.1 mol % or less based on total moles in the vapor phase.

In a sixth aspect, a semiconductor grade dimethylaluminum chloride (DMAC) material having a purity of 99.9 mol % or higher, said semiconductor grade DMAC material comprising impurities, said impurities comprising at least one of hydrocarbons, moisture, hydrides, chlorides, alkyl-aluminum compounds and corresponding chlorine derivatives and atmospheric gases selected from the group consisting of H2, O2, N2, Ar, CO2 and CO; whereby an aggregate amount of said impurities is greater than 0 mol % and up to about 0.1 mol %, a balance being said semiconductor grade DMAC material.

In a seventh aspect, a method of filling a canister configured for delivery of semiconductor grade DMAC material having a purity of 99.9 mol % or higher, comprising the steps of: providing the canister that is hermetically or substantially sealed; outgassing an interior volume of the canister; passivating interior walls of the canister to remove residual solvents, moisture, particles and/or other impurities adsorbed onto the interior walls; followed by introducing a semiconductor grade DMAC material having a purity of 99.9 mol % or higher into the canister, whereby air ingress is excluded to maintain the purity of 99.9 mol % or higher.

In an eight aspect, a semiconductor grade dimethylaluminum chloride (DMAC) material having a purity of 99.9 mol % or higher, said semiconductor grade DMAC material comprising impurities, said impurities comprising at least one of hydrocarbons, moisture, hydrides, chlorides, alkyl-aluminum compounds and corresponding chlorine derivatives, atmospheric gases selected from the group consisting of H2, O2, N2, Ar, CO2 and CO; whereby an aggregate amount of said impurities is greater than 0 mol % and up to about 0.1 mol %, a balance being said DMAC material; with the proviso that when the impurities comprises hydrocarbons, the hydrocarbons comprises one or more of CH4, C2H6, C2H4, C3H8, C3H6, C4H10, C5H12, C6H14, C7H16, or CxHy, where x is an integer and y=2x−2, 2x, or 2x+2; with the proviso that when the impurities comprises hydrides, said hydrides comprises one or more of SixHy, GexHy, NH3, PH3, AsH3 and SbH3, where x and y are greater than 0 and can have any integer value; with the proviso that when the impurities comprises chlorides, said chlorides comprises one or more of SixHyClz, GexHyClz, COCl2, MoO2Cl2, SOCl2, C12, HCl, CCl4, CHCl3, CH2Cl2, CHCl3, SiCl4, and TiCl4, where x, y and z are greater than 0 and can have any integer value; with the proviso that when the impurities comprises alkyl-aluminum compounds and corresponding chlorine derivatives, said alkyl-aluminum compounds and corresponding chlorine derivatives comprises one or more of Al(CH3)3, CH3AlCl2 and (C2H5)xAlCly where x and y are greater than 0 and can have any integer value.

In a ninth aspect, a method of using semiconductor grade dimethylaluminum chloride DMAC, comprising the step of: providing a canister at least partially filled with a liquid phase of the semiconductor grade DMAC material; withdrawing the liquid phase of the semiconductor grade DMAC material from the canister at a semiconductor grade purity of 99.9 mol % or higher; directing the liquid phase of the semiconductor grade DMAC material to an intermediate buffer vessel; accumulating a sufficient amount of the DMAC material into the intermediate buffer vessel until a stable flow of DMAC vapor from the intermediate buffer vessel can occur; dispensing the DMAC vapor from the intermediate vessel to a downstream tool for atomic layer etching in connection with a semiconductor fabrication process, said DMAC vapor being introduced into the downstream tool at the semiconductor grade purity of 99.9 mol % or higher.

In a tenth aspect, a semiconductor grade dimethylaluminum chloride (DMAC) source material suitable for use in an improved aluminum ion implant process, said DMAC source material having a purity of at least about 99 mol % or greater based on total moles in the DMAC source material with reduced levels of impurities therein capable of generating C2H3 ions; said impurities therein capable of generating C2H3 ions comprising at least one or more of the following: (i) hydrocarbons represented by the general formula of CxHy, with x equal to 2 and y equal to any integer satisfying valency rules for saturated, unsaturated, cyclic, aromatic and other hydrocarbon compounds; (ii) halogen derivatives of hydrocarbons represented by the general formula CxHyHalz, with x equal to 2 and “Hal” being either Cl, F, Br or I; (iii) alkyl or alkoxy halides or hydrides of aluminum including (C2H5)x(CH3)yAlClz, where x, y, or z=0 to 3, and x+y+z=3; (C2H5)3A1; (C2H5)2AlCl; (C2H5)AlCl2; (C2H5)2(CH3)Al; (C2H5)(CH3)2A1; and (C2H5)(CH3)AlCl; and their dimers and trimers; (iv) alkyl or alkoxy halides or hydrides of silicon including (C2H5)x(CH3)y4SiClz, where x, y, or z=0 to 4, x+y+z=4; (C2H5)4Si; (C2H5)3SiCl; (C2H5)2SiCl2; (C2H5)SiCl3; (C2H5)(CH3)3Si; (C2H5)(CH3)2SiCl; and(C2H5)(CH3)SiCl2; and (v) alkyl, alkylidene, alkoxy functionalities including ethyl (H3C-CH2-), vinyl (H2C═CH—), ethoxy (H3C-CH2-O—); whereby an aggregate amount of said impurities therein capable of generating C2H3 ions is greater than 0 mol % and less than about 1 mol %, with a balance being said semiconductor grade DMAC material.

In an eleventh aspect, a semiconductor grade dimethylaluminum chloride (DMAC) source material suitable for use in an improved aluminum ion implant process, said DMAC source material having a purity of at least about 99 mol % or higher, said semiconductor grade DMAC source material comprising reduced levels of one or more impurities therein capable of generating C2H3 ions, whereby an aggregate amount of said one or more impurities therein capable of generating C2H3 ions is greater than 0 mol % and up to about 1 mol %, with a balance being said semiconductor grade DMAC material.

In a twelfth aspect, an improved method for performing aluminum ion implantation, comprising the steps of: withdrawing high purity DMAC source material in a vapor phase from a storage and delivery package, said DMAC source material in the vapor phase having a purity of at least about 99 mol % or higher, said semiconductor grade DMAC source material comprising reduced levels of one or more impurities therein capable of generating C2H3 ions in an amount greater than 0 mol % and up to about 1 mol %; flowing the high purity DMAC source material in the vapor phase without a co-flow gas configured to scavenge said C2H3 ions; introducing said high purity DMAC source material into an ion source chamber.

The invention may include any of the aspects in various combinations and embodiments to be disclosed herein.

### DETAILED DESCRIPTION OF THE INVENTION

The advantages of the invention will be better understood from the following detailed description of the embodiments thereof in connection. The disclosure is set out herein in various embodiments and with reference to various features, aspects and embodiments of the invention, each of which may be employed in various permutations and combinations without departing from the scope of the invention. The disclosure may further be specified as comprising, consisting or consisting essentially of, any of such permutations and combinations of these specific features, aspects, and embodiments, or a selected one or ones thereof.

All percentages are expressed herein as molar percentages, designated as mol %, unless specified otherwise, with the understanding that volume percentage, designated as vol %, and mol % are equivalent for gases and therefore may be utilized interchangeably for expressing concentrations of gases.

The terms “sufficiently”, “adequately”, “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

Various aspects of the present invention may be presented in range format. Where a range of values describes a parameter, all sub-ranges, point values and endpoints within that range or defining a range are explicitly disclosed therein, unless explicitly disclosed otherwise. All physical property, dimension, concentration and ratio ranges and sub-ranges between range end points for those physical properties, dimensions, concentrations and ratios are considered explicitly disclosed herein, unless explicitly disclosed otherwise. For example, description of a range such as from 1 to 10 shall be considered to have specifically disclosed sub-ranges such as from 1 to 7, from 2 to 9, from 7 to 10 and so on, as well as individual numbers within that range such as 1, 5.3 and 9.

“GC-FID” means gas chromatography with flame ionization detector

“CRDS” means cavity ring-down spectroscopy.

“FTIR” means Fourier-transform infrared spectroscopy.

“GC-MS” means gas chromatography with a mass spectrometer detector.

“Semiconductor grade” and “high purity” are used interchangeably herein and throughout to mean a purity of 99.9 mol % or higher for ALE applications and 99 mol % or higher for ion implant applications.

“Low grade” means a purity level that is less than 99.9 mol % and/or not qualified for use in semiconductor applications.

“Semiconductor applications” includes, but is not limited to, fabrication of Gate-All-Around (GAA) and 3D NAND structures.

“High precision atomic layer etchant” or “high precision etchant” or “etch precision” may be used interchangeably herein to mean atomic layer removal of material from features, structures or devices characterized as having relatively high aspect ratios, where aspect ratio is the ratio of the height to depth of the feature, structure or device.

“Etch selectivity ratio” means the ratio of an amount of favorable material to be etched relative to an amount of unwanted material to be etched from any feature, structure or device.

“Feature, structure or device” includes, but is not limited to any aspect, portion or component of a 3D NAND structure or other semiconductor component.

“DMAC Material” or “Material” as may be used interchangeably herein and throughout is intended to mean, without further qualification, liquid phase and/or vapor phase dimethylaluminum chloride.

The inventors have observed that although several etchants are commercially available for use in ALE processes, none have emerged as a suitable material for ALE in the production of various semiconductor applications, such as advanced 3D NAND memory devices. For example, while U.S. Pat. No. 10,381,227 to George et al provides a list of representative etchants, including low grade DMAC, that were evaluated on a laboratory scale for technical feasibility, George et al. and others have not been able to identify a particular high purity, semiconductor grade etchant with a compositional profile suitable for effective commercial use in semiconductor applications such as 3D NAND processes. Of particular significance, no one has recognized or determined which combination of impurities contained in a specific etchant are detrimental and adversely impact etchant performance, and at what upper concentration limit, if any, can each of the impurities be tolerated in the etchant without negatively impacting its ALE performance in various semiconductor applications such as 3D NAND fabrication processes.

It is from these deficiencies in the current state of the art that the present invention has emerged. In one aspect of the present invention, the inventors have identified that a high purity DMAC material with a composition of 99.9 mol % or higher can operate as a superior atomic layer etchant for semiconductor applications, and more preferably processes for fabricating 3D NAND devices. However, high purity DMAC of at least 99.9 mol % is not sufficient for ALE in semiconductor applications, as the present invention has recognized that certain impurities within the high purity DMAC material must be controlled to not exceed their respective upper concentration limits. In one embodiment, the balance of the high purity DMAC material may contain traceable impurities in the form of gaseous impurities that are in an aggregate amount of 0.1 mol % or less as measured by specific metrology to be disclosed herein.

The high purity of 99.9 mol % or higher DMAC exhibits favorable etch selectivity of various metal oxides, such as Al2O3, HfO2, ZrO2 (favorable material to be etched) relative to materials of Si, SiO2, Si3N4 and TiN (unwanted material to be etched) at an etch ratio of 10:1 or higher. The selective etching of such metal oxides can occur at acceptably high etch rates (typically defined in Angstroms of the metal oxide material removed per cycle), and, advantageously, in a manner that creates acceptably low film roughness. Additionally, the DMAC composition has the ability to selectively etch with high precision various 3D NAND structures, which in some instances have an aspect ratio of more than 50:1. Each of these performance traits of the high purity DMAC composition are desirable for use in ALE methods for fabricating 3D NAND.

To ensure all of the above-mentioned etchant performance traits of a semiconductor grade DMAC for 3D NAND fabrication processes can be achieved, the present invention defines an impurity profile. The impurity profile is a specific combination of impurities in the semiconductor grade DMAC material that cannot exceed a corresponding upper concentration limit, thereby avoiding a risk of adverse etchant performance during atomic layer removal of certain material (e.g., metal oxides) for 3D NAND fabrication processes. Additionally, the reduction of the impurities at or below their respective upper concentration limit reduces or minimizes the risk of device yield or throughput of the 3D NAND devices.

In accordance with the principles of the present invention, a high purity, DMAC composition is provided that can be used as a high precision, atomic layer etchant with etch selectivity for semiconductor applications by maintaining a combination of specifically identified gaseous impurities at or below a predetermined upper concentration limit. The storage conditions for the DMAC material can allow a liquid phase to be in substantial equilibrium with a corresponding high purity, vapor phase of the DMAC. Certain impurities exist in DMAC that are partitioned between the vapor phase and liquid phase based on their respective K-values, which is indicative of a vapor-liquid distribution ratio (i.e., ratio of the amount of a particular impurity occupying the vapor phase to that in the liquid phase). High K-value impurities, including, but not limited to, volatile solvents such as methanol, methylchlorides, light ethers and trimethylaluminum, are volatile gaseous impurities that preferentially partition more into the vapor phase as opposed to the liquid phase. Low K-value impurities, including but not limited to methylaluminum chloride, CCl4, higher chlorine-substituted hydrocarbons and low boiling organic solvents, are relatively non-volatile and preferentially partition more in the liquid phase. However, as DMAC material in the vapor phase is delivered for use for ALE processes, additional low K-value impurities in the liquid phase will vaporize to replenish the vapor phase and restore the liquid-vapor equilibrium of the low-K impurities. As a result, the low K-value impurities cannot be disregarded. The present invention aims to control the amount of both high K-value and low K-value impurities in the DMAC material to ensure reliable and continuous supply of a high purity, vapor phase of DMAC material for use in ALE.

Accordingly, maintaining several types of gaseous impurities at or below a threshold value in the vapor phase of DMAC is required. Atmospheric gases in the vapor phase of the DMAC are considered a gaseous impurity and maintained at or below 0.1 mol % based on total moles in the vapor phase. Atmospheric impurities of relevance include hydrogen, nitrogen, oxygen, argon, carbon monoxide and carbon dioxide. Preferably, the atmospheric gaseous impurities have upper concentration limits at or below 0.01 mol % and more preferably at or below 0.001 mol % in the vapor phase. The atmospheric impurities can be measured by GC-TCD, GC-DID, GC-PDHID, GC-MS, or other metrologies.

Hydrocarbons are a second gaseous impurity that can occupy the vapor phase of the DMAC. Hydrocarbons can be represented by the general formula CxHy where x and y are integer values greater than 0. Typical hydrocarbons expected to occupy the vapor phase of the DMAC include CH4, C2H6, C2H4, C3H8, C3H6 or any combination thereof. Many of such hydrocarbons are volatile (i.e., high K-value impurities) and have a tendency to reduce the DMAC etch rate as well as reduce the etch selectivity of DMAC. To avoid adverse etch performance, the hydrocarbons are maintained at or below 0.1 mol % based on total moles in the vapor phase. Preferably, the hydrocarbon gaseous impurities are maintained at or below 0.01 mol % and more preferably at or below 0.001 mol % in the vapor phase to ensure the presence of hydrocarbons in the vapor phase does not reduce rate etch rate or etch selectivity of the 99.9 mol % or higher purity DMAC during a semiconductor application. The hydrocarbons can be measured by GC-FID, or other gas chromatography metrologies.

Moisture is a third impurity that can occupy the vapor phase of the DMAC. Moisture is maintained at or below 0.1 mol % based on total moles in the vapor phase. Preferably, the moisture has an upper concentration limit at or below 0.01 mol % and more preferably at or below 0.001 mol % in the vapor phase. The moisture can be measured by CRDS or FTIR metrology.

Volatile hydrides are a fourth impurity that can occupy the vapor phase of the DMAC. Volatile hydrides comprise at least one of SixHy, GexHy, NH3, PH3, AsH3 and SbH3, where x and y are greater than 0 and can have any integer value. Volatile hydrides are maintained at or below 0.1 mol % based on total moles in the vapor phase. Preferably, the volatile hydrides have upper concentration limits at or below 0.01 mol % and more preferably at or below 0.001 mol % in the vapor phase. The volatile hydrides can be measured by GC-MS or FTIR metrology.

Chloride derivatives of the above mentioned volatile hydrides are a fifth impurity that can occupy the vapor phase of the DMAC. Chloride derivatives of the volatile hydrides comprise at least one of SixHyClz and GexHyClz, where x, y and z are greater than 0 and can have any integer value. Chloride derivatives are maintained at or below 0.1 mol % based on total moles in the vapor phase. Preferably, the chloride derivatives have an upper concentration limit at or below 0.01 mol % and more preferably at or below 0.001 mol % in the vapor phase. The chloride derivatives can be measured by GC-MS or FTIR metrology.

Volatile chlorides are a sixth impurity that can occupy the vapor phase of the DMAC. Volatile chlorides include at least one of C12, HCl, CCl4, SiCl4 and TiCl4. Volatile chlorides are maintained at or below 0.1 mol % based on total moles in the vapor phase. Preferably, the volatile chlorides have an upper concentration limit at or below 0.01 mol % and more preferably at or below 0.001 mol % in the vapor phase. The volatile chlorides can be measured by GC-MS or FTIR metrology.

Oxy-chlorides are a seventh impurity that can occupy the vapor phase of the DMAC. Oxy-chlorides comprise at least one of at least one of COCl2, MoO2Cl2 and SOCl2. Oxy-chlorides are maintained at or below 0.1 mol % based on total moles in the vapor phase. Preferably, the oxy-chlorides have an upper concentration limit at or below 0.01 mol % and more preferably at or below 0.001 mol % in the vapor phase. The volatile chlorides can be measured by GC-MS or FTIR metrology.

Alkyl-aluminum compounds and corresponding chlorine derivatives thereof are an eighth impurity that can occupy the vapor phase of the DMAC. Alkyl-aluminum compounds and corresponding chlorine derivatives thereof comprise at least one of Al(CH3)3, CH3AlCl2 and (C2H5)xAlCly where x and y are greater than 0 and can have any integer value. Alkyl-aluminum and their corresponding chlorine derivates are maintained at or below 0.1 mol % based on total moles in the vapor phase. Preferably, alkyl-aluminum and their corresponding chlorine derivates have an upper concentration limit at or below 0.01 mol % and more preferably at or below 0.001 mol % in the vapor phase. The alkyl-aluminum and their corresponding chlorine derivates can be measured by GC-MS or FTIR, metrology.

By maintaining each of the above mentioned gaseous impurities at or below their respective upper concentration limits, the amounts of gaseous impurities that co-flows and/or is entrained with the vapor phase of the DMAC during an etch process is expected to be insubstantial so as to not dilute the DMAC high purity, vapor phase and reduce performance traits (e.g., etch rate, etch selectivity and etch precision) of the DMAC high purity, vapor phase. To the extent any of the gaseous impurities are active impurities, which are defined herein as having a tendency to etch unwanted material of any features, devices and structures, the reduction of each of the gaseous impurities to an amount that is at or below its respective upper concentration limit can reduce, minimize or eliminate the risk of the DMAC etchant selectivity being lowered to produce an irreparable defect that can ruin the structure being fabricated. For example, active impurities of oxy-chlorides such as SOCl2 exhibit greater etch selectivity to TiN over Al2O3 and even in relatively small concentrations in DMAC, SOCl2 can undesirably etch TiN while DMAC etches the fluorinated surface of Al2O3 film to produce AlF3, thereby undesirably reducing etch selectivity. The present invention aims to reduce, minimize or eliminate the deleterious effects of such active impurities.

The present invention further requires maintaining a combination of specifically identified liquid impurities in the liquid phase of the DMAC at or below a predetermined upper concentration limit. Specifically, liquid phase impurities contained in the liquid phase may include (i) hydrocarbons of a general formula represented by CxHy where x and y are greater than 0 and can have any integer value; (ii) moisture, H2O; (iii) metals in an amount greater than 0 mol % and up to about 0.01 mol %; (iv) hydrides comprising at least one of SixHy, GexHy, NH3, PH3, AsH3 and SbH3 where x and y are greater than 0 and can have any integer value; (v) chloride derivatives of the volatile hydrides; (vi) chlorides; (vii) oxychlorides of the chlorides; and (viii) alkyl-aluminum compounds and corresponding chlorine derivatives thereof. With the exception of the metals, each of said liquid phase impurities in the liquid phase is contained in an amount greater than 0 mol % and up to about 0.1 mol % with the proviso that an aggregate amount of all of the gaseous impurities is no greater than about 0.1 mol %. In another embodiment, each of said liquid phase impurities in the liquid phase is contained in an amount greater than 0 mol % and up to about 0.01 mol % with the proviso that an aggregate amount of all of the liquid phase impurities is no greater than about 0.01 mol %. In yet another embodiment, each of said liquid phase impurities in the liquid phase is contained in an amount greater than 0 mol % and up to about 0.001 mol % with the proviso that an aggregate amount of all of the liquid phase impurities is no greater than about 0.001 mol %.

Impurities in the liquid phase can be measured by NMR or GC-MS with direct sampling. Metals can be measured by ICP-MS, or ICP-OES with indirect sampling that includes DMAC hydrolysis.

Having identified a combination of specific impurities and their respective upper concentration limits that are permissible without adversely affecting DMAC etching performance, the present invention further takes into account that commercially available low grade DMAC material will require undergoing one or more specific purification processes to achieve the desired semiconductor grade purity. Various purification processes are contemplated. The exact purification depends on the type of impurities present in low grade DMAC and their respective concentrations. By way of non-limiting example, low grade DMAC may undergo rectification, distillation, freeze-pump-thaw, adsorption, or a combination thereof to achieve an impurity profile with the upper concentration limits as mentioned hereinabove. In this manner, the low grade DMAC material is converted to a suitable semiconductor grade DMAC material.

After DMAC material purification, the DMAC purified material is subsequently filled under certain storage conditions that allows the high purity vapor phase of DMAC to remain at a high purity in a headspace of a storage source such as a canister that is hermetically or substantially sealed to ensure atmospheric impurities do not enter into the canister. Furthermore, canister passivation is employed to avoid another source of contamination of the DMAC high purity material from various surfaces of the canister. Specifically, canister passivation is required to remove residual solvents, moisture, particles and other impurities that can desorb from the surfaces of the canister upon filling DMAC therein or react with the DMAC material over its shelf life period. Alternatively, or in addition thereto, active sites on the materials of construction of the canister can themselves react with DMAC or catalyze its decomposition. One example of a suitable preparation of the canister prior to filling the purified DMAC material includes (i) outgassing through pumping, purging, cycle-purging at room or elevated temperatures; (ii) pickling with an active solution to render canister surfaces inactive; and (iii) passivation at room or elevated temperatures with passivation gases such as F2, Cl2 O2, other active fluorine-containing, chlorine-containing, or oxygen-containing chemicals or mixtures thereof or DMAC or other alkyl-aluminum chlorides. The canister is leak-tight (e.g., substantially hermetically sealed) and can be filled with a blanket gas to ensure air ingress does not occur during storage and transport. In this manner, suitable storage conditions are created that allow the high purity DMAC composition to be maintained and remain chemically stable without underdoing decomposition. In conjunction with the purification of DMAC material and canister passivation, suitable metrology methods of analysis for the specific target impurities mentioned hereinabove can be modified, customized and/or developed, including those for FTIR, various GC methods, MS, NMR, and CRDS with direct and indirect sampling.

DMAC can be filled into the canister either as a liquid or as a gas. One exemplary method for liquid fill involves connecting the canister to a source vessel with a dip tube extending into the liquid phase of DMAC. The source vessel is pressurized by an inert pusher gas such as nitrogen, argon, helium, or other suitable gas and the liquid DMAC is pushed out of the source vessel and into the canister. The pressure of the canister is maintained sufficiently low to allow a controlled transfer of liquid DMAC. The inert pusher gas can be kept as a blanket gas inside the canister.

Vapor fill involves DMAC transfer via the vapor phase from a source vessel into a canister. In one exemplary method, the source vessel can be optionally heated to a predetermined temperature to create a pressure substantially higher that the pressure of the canister. The canister can be optionally cooled to reduce pressure for more efficient DMAC transfer. The canister can be kept under DMAC vapor pressure or a blanket gas such as N2, Ar, or He can be added into the canister headspace. In one embodiment, the blanket gas will generally be held at a pressure of 1 atmosphere and not substantially disrupt the equilibrium between the liquid phase of the DMAC and its corresponding vapor phase that occupies the headspace within the canister.

The high purity DMAC compositions of the present invention allow for its usage as a suitable material for ALE in a semiconductor application where semiconductor grade purity levels are required. In a preferred embodiment, selective ALE of HfO2 using alternative doses of HF with the high purity DMAC composition can be employed. In a first step, surface modification of a HfO2 surface occurs to fluorinate the surface with HF with formation of a HfF4 layer and water as a by-product. Subsequently, in a second step, high purity DMAC in the vapor phase can be delivered from a suitable delivery device, such as the passivated canister described hereinabove or an intermediate vessel located on the ALE tool that is filled from the passivated canister. The high purity DMAC is a metal-based precursor that accepts fluorine from the HfF4 layer and donates a chlorine ligand to the Hf metal in the metal fluoride to form HfCl4 as a volatile by-product. This ligand exchange process forms volatile reaction products (CH3)2AlF and HfCl4 that causes removal of the HfF4 layer. The DMAC material by virtue of its semiconductor grade purity of 99.9 mol % or higher is capable of high precision etching with high etch selectivity of 10:1 or greater in favor of HfO2 material to be etched relative to undesired etch material (e.g. Si, SiO2, Si3N4 and TiN) to be etched from the 3D NAND structure, whereby the 3D NAND structure has an aspect ratio of more than 50:1. In this manner, one or more cycles of HF followed by feeding the DMAC high purity composition material is used to selectively remove material on an atomic basis from all feature walls equally at top and bottom of trenches of the 3D NAND structure with high precision and with acceptably high etch rate to produce features, structures and/or devices with acceptably low film roughness.]

Operating parameters for the use of the high purity DMAC material in ALE processes such as temperature, pressure, reaction times, canister volume, and flowrate can be carried out as known in the art, for example, as disclosed in U.S. Pat. No. 10,381,227 to George et al.

Although selective etching has been described with regards to a HfO2 surface, other metal oxide surfaces can be selectively etched in accordance with the principles of the present invention. For example, other non-limiting examples of suitable metal oxides can include Al2O3, ZrO2, ZnO and TiO2.

The DMAC material can be delivered in several ways. One exemplary delivery method involves withdrawing a portion of the liquid semiconductor grade DMAC material from the canister and introducing the liquid semiconductor grade DMAC material into an intermediate buffer vessel. The intermediate buffer vessel may be integrated into a delivery system. The purity of the DMAC material is preferably maintained as it transfers from the canister into the intermediate buffer vessel. Liquid semiconductor grade DMAC material continues to fill into the intermediate buffer vessel until a sufficient amount of DMAC material has accumulated therein until stable flow of DMAC vapor from the intermediate vessel can occur. It should be understood that more than one intermediate buffer vessel can be utilized to transfer the high purity, liquid phase of DMAC. Upon accumulating the prerequisite volume of liquid material, which is in substantial equilibrium with its high purity, DMAC vapor phase, the DMAC vapor in the intermediate vessel can be dispensed to a downstream tool such as an ALE tool. The vapor has a semiconductor grade purity of 99.9 mol % or higher. The vapor can flow under its own vapor pressure to the downstream tool. Alternatively, the delivery of the vapor to the downstream tool can occur by employing a carrier gas, which can either sweep the headspace of the intermediate buffer vessel or can be pulled through the liquid phase of the semiconductor grade DMAC material. Either method results in steady, sustained and sufficient flow of 99.9 mol % or higher DMAC vapor into the downstream tool.

In another embodiment, a high purity DMAC composition suitable for use as an atomic layer etchant (ALE) in a semiconductor fabrication process comprises gaseous impurities in the high purity, vapor phase with an impurity profile that is categorized as follows: (i) atmospheric gases having at least one of H2, O2, N2, Ar, CO2, CO and any combination thereof, in which each of said atmospheric gases is greater than 0 and up to about 10 ppmv based on total moles in the vapor phase as measured by GC-PDID; (ii) hydrocarbons having at least one of SixHy, GexHy, NH3, PH3, AsH3 and SbH3, where x and y are greater than 0 and can have any integer value, and in which an aggregate of the hydrocarbons is in an amount greater than 0 and up to about 50 ppmv based on total moles in the vapor phase as measured by GC-FID; (iii) moisture, H2O, in an amount greater than 0 and up to about 10 ppmv based on total moles in the vapor phase as measured by CRDS and/or FTIR; (iv) volatile chlorides having at least one of C12, HCl, CCl4, SiCl4 and TiCl4 and oxy-chlorides of the volatile chlorides including at least one of COCl2, MoO2Cl2 and SOCl2, in which the volatile chlorides and the oxy-chlorides are in an aggregate amount of greater than 0 and up to about 50 ppmv based on total moles in the vapor phase as measured by FTIR and/or GC-MS; and (v) alkyl-aluminum compounds and corresponding chlorine derivatives thereof comprise at least one of Al(CH3)3, CH3AlCl2 and (C2H5)xAlCly where x and y are greater than 0 and can have any integer value, in which the aggregate amount of the alkyl-aluminum compounds and corresponding chlorine derivatives are greater than 0 and up to about 100 ppmv total based on total moles in the vapor phase as measured by GC-MS.

In certain applications, especially semiconductor applications where miniaturization of features, devices and structures require smaller nodes to be fabricated, etching atomic layer-by-atomic layer may require higher purity levels of the DMAC etchant to achieve higher precision etchant performance and higher etch selectivity. Accordingly, higher purity levels for DMAC are contemplated beyond 99.9 mol %, including, by way of non-limiting example, 99.99 mol % or 99.999 mol %. In such instances, where higher purity of DMAC is required, a further reduction of the upper concentration limit of each of the impurities in both the liquid phase and vapor phase mentioned hereinabove may be required to enable sufficient performance of the high purity, vapor phase DMAC as a high performance etchant.

It should be understood that the present invention contemplates other semiconductor applications for high purity DMAC source material. By way of non-limiting example, and in accordance with another embodiment of the present invention, a novel high purity DMAC source material with a specific impurity profile is provided to perform an improved Al ion implantation process. The inventors have discovered that the presence of impurities in the DMAC source material capable of generating C2H3 ions (e.g., C2H5) must be maintained at or below a certain upper concentration limit to avoid increased levels of impurities therein that are available for ionization with aluminum in the generated plasma within the ion chamber. C2H5 upon ionization produces C2H3 ions with an atomic mass of 27, which is identical to that of aluminum. Because of the identical atomic mass of C2H3 and aluminum, the mass analyzing magnet of the ion implanter cannot selectively deflect or remove the C2H3 ion contaminants from the path of the Al ion beam because there is no atomic mass difference between the species. Consequently, the C2H3 ion contaminant is unintentionally implanted into the wafer device. The C2H3 contaminants when implanted have the adverse effect of reducing wafer device efficiency and/or causing failure of the wafer device.

By maintaining the C2H5 at or below a certain upper concentration limit in the DMAC source material, the Al-based ion beam has significantly reduced levels of C2H3 in comparison to conventional commercially available DMAC materials. The benefit is a reduced amount of C2H5 molecules are ionized to C2H3, thereby reducing the amount of contamination in the plasma by C2H3 that is available to contaminate the Al-based ion beam.

In a preferred embodiment, a composition of matter for DMAC suitable for use in Al ion implantation processes is provided whereby high purity DMAC is purified to a level of 99 mol % or greater with reduced levels of C2H5 impurities that are capable of producing C2H3 ions with atomic mass as aluminum 27. Specifically, the presence of impurities capable of generating C2H3 ions in aggregate within the high purity DMAC source material is reduced to levels of less than about 1 mol %, preferably less than about 0.1 mol % and more preferably less than about 0.01 mol % whereby “about” means plus or minus 10% of the target value. By maintaining the impurities capable of generating C2H3 ions at or below these prescribed levels, the contamination ions is substantially reduced in comparison to that observed when utilizing commercially available DMAC source material. In one example, the amount of C2H5 groups in the high purity DMAC source material has been reduced by about 10× or more, preferably about 100× or more and more preferably about 1000× or more over commercially available DMAC materials.

The impurity profile of the high purity DMAC source material may include one or more of the following groups of impurities capable of generating C2H3 ions, as will now be discussed, in an aggregate amount that is less than about 1 mol %, preferably less than about 0.1 mol % and more preferably less than about 0.01 mol %, whereby “about” means plus or minus 10% of the target value.

A first group of impurities may include hydrocarbons of the general formula of CxHy, with x equal to 2 and y equal to any integer satisfying valency rules for saturated, unsaturated, cyclic, aromatic and other hydrocarbon compounds.

A second group of impurities in the DMAC source material may include halogen derivatives of hydrocarbons of general formula CxHyHalz, with x equal to 2 and “Hal” being either Cl, F, Br or I.

A third group of impurities in the high purity DMAC source material can include alkyl or alkoxy halides or hydrides of aluminum including (C2H5)x(CH3)yAlClz, where x, y, or z=0 to 3, and x+y+z=3; (C2H5)3A1; (C2H5)2AlCl; (C2H5)AlCl2; (C2H5)2(CH3)Al; (C2H5)(CH3)2A1; and (C2H5)(CH3)AlCl, and their dimers and trimers.

A fourth group of impurities in the DMAC source material can include alkyl or alkoxy halides or hydrides of silicon including (C2H5)x(CH3)y4SiClz, where x, y, or z=0 to 4, x+y+z=4; (C2H5)4Si; (C2H5)3SiCl; (C2H5)2SiCl2; (C2H5)SiCl3; (C2H5)(CH3)3Si; (C2H5)(CH3)2SiCl; and(C2H5)(CH3)SiCl2.

A fifth group of impurities in the DMAC source material may include alkyl, alkylidene, alkoxy functionalities such as ethyl (H3C-CH2-), vinyl (H2C═CH—), ethoxy (H3C-CH2-O—) and the like.

One or more species from the aforementioned first group, second group, third group, fourth group and fifth group may be present in the high purity DMAC source material, provided that an aggregate amount of said species is less than about 1 mol %, preferably less than about 0.1 mol % and more preferably less than about 0.01 mol %. By maintaining the one or more species at the upper concentration limits in the high purity DMAC source material, there is a reduction in the number of C2H3 ions that are produced in the ion chamber. Contrary to the present invention, due to the abundance of C2H3 ions derived from commercially available DMAC materials, prior techniques have attempted to sequester the C2H3 ion contaminants by adding a co-flow gas. Specifically, the co-flow gas contains fluorine molecules which combine with the contaminant to significantly change the mass of the C2H3 contaminant, thereby allowing it to be eliminated from the implant beam via a mass analyzing magnet. However, in accordance with the principles of the present invention, the DMAC aluminum ion implant source has a reduced concentration of C2H5 contaminants that ionize to C2H3 with atomic mass 27 in the ion chamber, thereby eliminating the need for a co-flow gas to alter these contaminants to a higher atomic mass that can subsequently be removed via the mass analyzing magnet. The present invention enables the ion beam to be comprised of atomic mass 27 ions, which are predominantly aluminum. In this manner, the Al ion implant process of the present invention reduces, minimizes or avoids implantation of C2H3 ions and offers a substantially simplified and improved process compared to conventional Al ion implant processes. In accordance with another aspect of the present invention, a method for implanting aluminum ions into a workpiece is provided. The method, by way of example, includes providing high purity DMAC source material to an ion source. The high purity DMAC source material is contained in a suitable storage and delivery package. The storage and delivery package may be a cylinder for holding the high purity DMAC source material in at least partial vapor phase under sub-atmospheric conditions therewithin. The high purity DMAC source material remains chemically stable and does not undergo decomposition within the interior of the cylinder. The high purity DMAC source material is preferably stored as a liquid at ambient temperature (e.g., 20-25° C.) and possesses sufficient vapor pressure without use of heat. The high purity DMAC source material in the cylinder is operably connected to an ion implanter where it is ionized in the ion source to produce substantially atomic mass 27 ions, which are predominantly aluminum. The amount of C2H5 impurities, which can be any one or more species of the aforementioned groups 1, 2, 3, 4 and/or 5 described hereinabove, is negligible in the plasma upon ionization so as to not require removal by a co-flow fluorine-based gas.

The Al-based ion beam is subsequently transported to a surface of the workpiece. The aluminum ions penetrate into the workpiece to form a doped region with the desired electrical and physical properties. The aluminum ions are implanted without substantial implantation of C2H3 impurity ionic species into a wafer device, thereby avoiding degradation or failure of the wafer device.

The present invention has several benefits. For example, the present invention includes the elimination of the costs, storage and handling of highly toxic, corrosive, oxidizing fluorine-based mixtures that must be co-flowed to scavenge the C2H3 contaminants in the plasma. Contrary to current techniques that perform the Al ion implant process in a manner that attempts to remove the deleterious carbon-hydrogen compounds having atomic mass of 27, the present invention represents a notable departure by reducing or minimizing the number of deleterious carbon-hydrogen compounds in the source material, thereby reducing or minimizing the level of contaminants in the plasma to a level that does not adversely affect device performance of the aluminum ions implanted therein. Additionally, in comparison to solid aluminum sources, the present invention allows for faster start-up times resulting in higher tool utilization.

Although the preferred embodiment of the DMAC source material is designed to minimize C2H5 impurities to improve the aluminum ion implant process by reducing, eliminating or minimizing C2H3 contaminants having an atomic mass of 27, it should be understood that the present invention can be implemented to ensure the DMAC source material reduces, eliminates or minimizes other contaminant sources which upon ionization can give rise to an atomic mass of 27. For example, B2H5, CBH4, HCN, HNC, NBH2, BO, C2DH are examples of source contaminants that yield an atomic mass of 27 when ionized. Hence, the high purity DMAC source material is formulated to reduce, eliminate or minimize such other impurities, besides C2H5, which upon ionization, can produce ions having an atomic mass of 27.

The above description with accompanying embodiments merely represents one possible arrangement of carrying out the invention. It should be understood that the metrology techniques disclosed hereinabove represent one possible analysis for determining the various impurities in the DMAC material. It will be appreciated that a wide variety of other metrology techniques that are functionally equivalent may be utilized as needed to define the impurity fingerprint profile of the high purity DMAC composition. Additionally, any suitable purification technique as known in the art or modification to those purification techniques described hereinabove can be employed to reduce the impurities to at or below their respective upper concentration limits. Still further, any suitable passivation technique can be employed to ensure contaminants from the canister do not degrade and/or contaminate the high purity DMAC material stored within the canister.

While it has been shown and described what is considered to be certain embodiments of the invention, it will, of course, be understood that various modifications and changes in form or detail can readily be made without departing from the spirit and scope of the invention. It is, therefore, intended that this invention not be limited to the exact form and detail herein shown and described, nor to anything less than the whole of the invention herein disclosed and hereinafter claimed.

1. A high purity dimethylaluminum chloride (DMAC) composition suitable for use as a high precision, atomic layer etchant (ALE) in a semiconductor fabrication process, said composition, comprising:
said high purity DMAC composition maintained under storage conditions in a liquid phase that is in substantial equilibrium with a high purity, vapor phase;
the high purity, vapor phase having a purity level of about 99.9 mol % or greater of the DMAC, based on total moles in the vapor phase wherein the total moles in the vapor phase excludes an optional blanket gas that may occupy said vapor phase, and further wherein a balance of the total moles in the vapor phase is occupied by gaseous impurities;
said gaseous impurities, comprising (i) atmospheric gases selected from the group consisting of H2, O2, N2, Ar, CO2, CO and any combination thereof; (ii) hydrocarbons of a general formula represented by CxHy where x and y are greater than 0 and can have any integer value; (iii) moisture, H2O; (iv) volatile hydrides; (v) chloride derivatives of the volatile hydrides; (vi) volatile chlorides; (vii) oxy-chlorides of the volatile hydrides; (viii) alkyl-aluminum compounds and corresponding chlorine derivatives thereof;
wherein each of said gaseous impurities is contained in an amount greater than 0 mol % and up to about 0.1 mol % with the proviso that an aggregate amount of all of the gaseous impurities is no greater than about 0.1 mol %.

2. The high purity DMAC composition of claim 1, wherein said hydrocarbons comprise at least one of CH4, C2H6, C2H4, C3H8, C3H6, C4H10, C5H12, C6H14, C7H16, or CxHy, where x is an integer and y=2x−2, 2x, or 2x+2.

3. The high purity DMAC composition of claim 1, wherein said chloride derivatives of the volatile hydrides comprise at least one of SixHyClz and GexHyClz, where x, y and z are greater than 0 and can have any integer value.

4. The high purity DMAC composition of claim 1, wherein said alkyl-aluminum compounds and corresponding chlorine derivatives thereof comprise at least one of Al(CH3)3, CH3AlCl2 and (C2H5)xAlCly where x and y are greater than 0 and can have any integer value.

5. The high purity DMAC composition of claim 1, wherein said volatile hydrides comprises at least one of SixHy, GexHy, NH3, PH3, AsH3 and SbH3, where x and y are greater than 0 and can have any integer value.

6. The high purity DMAC composition of claim 1, wherein said volatile chlorides comprises at least one of C12, HCl, CCl4, CHCl3, CH2Cl2, CHCl3, SiCl4, and TiCl4.

7. The high purity DMAC composition of claim 1, wherein the oxychlorides comprises at least one of at least one of COCl2, MoO2Cl2 and SOCl2.

8. The high purity DMAC composition of claim 1, wherein the amount of each of said atmospheric gases is contained at no greater than about 10 ppmv.

9. The high purity DMAC composition of claim 1, wherein the amount of said moisture is contained at no greater than about 10 ppmv.

10. The high purity DMAC composition of claim 2, wherein the amount of said hydrocarbons is no greater than about 50 ppmv.

11. The high purity DMAC composition of claim 1, wherein the amount of said volatile chlorides and said oxy-chlorides is no greater than about 50 ppmv.

12. The high purity DMAC composition of claim 1, wherein the amount of the alkyl-aluminum compounds and said corresponding chlorine derivatives is no greater than about 100 ppmv.

13. The high purity DMAC composition of claim 1, wherein said storage conditions of said high purity DMAC composition is adapted to maintain said purity level of about 99.9 mol % or greater and remain chemically stable at ambient temperature without undergoing decomposition under said storage conditions.

14. A high purity dimethylaluminum chloride (DMAC) composition suitable for use as a high precision, atomic layer etchant (ALE) in a semiconductor fabrication process, said composition, comprising:
said high purity DMAC composition maintained under storage conditions with a vapor phase that is in substantial equilibrium with a liquid phase;
the liquid phase having impurities;
said impurities contained in the liquid phase comprising (i) hydrocarbons of a general formula represented by CxHy where x and y are greater than 0 and can have any integer value; (ii) moisture, H2O; (iii) metals in an amount greater than 0 mol % and up to about 0.01 mol %; (iv) hydrides comprising at least one of SixHy, GexHy, NH3, PH3, AsH3 and SbH3 where x and y are greater than 0 and can have any integer value; (v) chloride derivatives of the volatile hydrides; (vi) chlorides; (vii) oxychlorides of the chlorides; and (viii) alkyl-aluminum compounds and corresponding chlorine derivatives thereof;
wherein each of said impurities in the liquid phase is contained in an amount greater than 0 mol % and up to about 0.1 mol % with the proviso that an aggregate amount of all of the liquid phase impurities is no greater than about 0.1 mol %.

15. The high purity DMAC composition of claim 14, wherein the amount of each of said metals is contained at no greater than about 1 ppmv.

16. The high purity DMAC composition of claim 14, wherein said hydrocarbons comprise at least one of CH4, C2H6, C2H4, C3H8 or C3H6.

17. The high purity DMAC composition of claim 14, wherein said chlorides comprises at least one of C12, HCl, CCl4, SiCl4 and TiCl4.

18. The high purity DMAC composition of claim 14, wherein the oxychlorides comprises at least one of at least one of COCl2, MoO2Cl2 and SOCl2.

19. The high purity DMAC composition of claim 14, wherein said chloride derivatives of the volatile hydrides comprise at least one of SixHyClz and GexHyClz, where x, y and z are greater than 0 and can have any integer value.

20. The high purity DMAC composition of claim 14, wherein said hydrides comprises at least one of SixHy, GexHy, NH3, PH3, AsH3 and SbH3, where x and y are greater than 0 and can have any integer value.

21. A high purity semiconductor grade DMAC composition maintained under storage conditions in a liquid phase that is in substantial equilibrium with a high purity vapor phase, whereby said high purity vapor phase of the high purity DMAC composition is configured for use as an atomic layer etchant with an etch selectivity ratio of species x to species y of about 10:1 or higher in a semiconductor fabrication process that uses HF as a first etchant gas followed by the high purity vapor phase of the high purity DMAC composition as the second etchant gas.

22. The high purity DMAC composition of claim 21, wherein the species x is selected from the group consisting of Al2O3, HfO2, ZrO2, ZnO and TiO2, and the species y is selected from the group consisting of Si, SiO2, Si3N4 and TiN, where any combination of the species x and the species y can be selectively etched at the etch selectivity ratio of 10:1 or higher in the semiconductor fabrication process.

23. A semiconductor grade dimethylaluminum chloride (DMAC) material stored in a substantially hermetically sealed and passivated canister, said DMAC material comprising a liquid phase in substantial equilibrium with a vapor phase occupying a predetermined headspace of the canister, said substantially hermetically sealed and passivated canister configured to maintain the vapor phase at a semiconductor grade purity level of 99.9 mol % or higher based on total moles in the predetermined headspace during transport, storage and use of the substantially hermetically sealed and passivated canister, wherein said total moles in the predetermined headspace excludes an optional blanket gas that may occupy said vapor phase.

24. A high purity dimethylaluminum chloride (DMAC) composition suitable for use as a high precision, atomic layer etchant (ALE) in a semiconductor fabrication process, said composition, comprising:
a substantially hermetically sealed and passivated canister;
said high purity DMAC composition maintained in the substantially hermetically sealed and passivated canister under storage conditions in a liquid phase that is in substantial equilibrium with a high purity, vapor phase;
the high purity, vapor phase having a purity level of about 99.9 mol % or greater of the DMAC, based on total moles in the vapor phase, wherein the total moles in the vapor phase excludes an optional blanket gas that may occupy said vapor phase, and further with a balance of the total moles in the vapor phase occupied by gaseous impurities;
said gaseous impurities occupying a headspace of a predetermined volume in the substantially hermetically sealed and passivated canister, said gaseous impurities comprising at least one of (i) atmospheric gases selected from the group consisting of H2, O2, N2, Ar, CO2, CO and any combination thereof; (ii) hydrocarbons comprising at least one of SixHy, GexHy, NH3, PH3, AsH3 and SbH3; (iii) moisture, H2O; (iv) volatile hydrides comprising at least one of SixHy, GexHy, NH3, PH3, AsH3 and SbH3; (v) chloride derivatives of the volatile hydrides wherein said chloride derivatives comprise at least one of SixHyClz and GexHyClz, where x, y and z are greater than 0 and can have any integer value; (vi) volatile chlorides comprising at least one of C12, HCl, CCl4, SiCl4 and TiCl4; (vii) oxy-chlorides of the volatile chlorides comprising at least one of COCl2, MoO2Cl2 and SOCl2; (viii) alkyl-aluminum compounds and corresponding chlorine derivatives thereof comprising at least one of Al(CH3)3, CH3AlCl2 and (C2H5)xAlCly where x and y are greater than 0 and can have any integer value;
whereby an aggregate amount of the gaseous impurities is 0.1 mol % or less based on total moles in the vapor phase.

25. A semiconductor grade dimethylaluminum chloride (DMAC) material having a purity of 99.9 mol % or higher, said semiconductor grade DMAC material comprising impurities, said impurities comprising at least one of hydrocarbons, moisture, hydrides, chlorides, alkyl-aluminum compounds and corresponding chlorine derivatives and atmospheric gases selected from the group consisting of H2, O2, N2, Ar, CO2 and CO;
whereby an aggregate amount of said impurities is greater than 0 mol % and up to about 0.1 mol %, a balance being said semiconductor grade DMAC material.

26. The DMAC material of claim 25, wherein said semiconductor grade DMAC material exhibits etch selectivity characteristics that is defined as an etch selectivity ratio of 10:1 or higher.

27. The semiconductor grade DMAC material of claim 26, wherein the etch selectivity ratio of 10:1 or higher is for selectively etching a species x to a species y, wherein the species x is selected from the group consisting of Al2O3, HfO2, ZrO2, ZnO and TiO2, and the species y is selected from the group consisting of Si, SiO2, Si3N4 and TiN, whereby any combination of the species x and the species y can be etched at the etch selectivity ratio of 10:1 or higher in a semiconductor fabrication process.

28. The semiconductor grade DMAC material of claim 25, wherein the DMAC material is maintained under storage conditions conducive for the semiconductor grade DMAC material to remain chemically stable without underdoing decomposition.

29. The semiconductor grade DMAC material of claim 25, wherein said impurities comprises said hydrocarbons further defined as at least one of CH4, C2H6, C2H4, C3H8, C3H6, C4H10, C5H12, C6H14, C7H16, or CxHy, where x is an integer and y=2x−2, 2x, or 2x+2.

30. The semiconductor grade DMAC material of claim 25, wherein said impurities comprises alkyl-aluminum compounds and corresponding chlorine derivatives, said alkyl-aluminum compounds and corresponding chlorine derivatives further defined as at least one of Al(CH3)3, CH3AlCl2 and (C2H5)xAlCly where x and y are greater than 0 and can have any integer value.

31. The semiconductor grade DMAC material of claim 25, wherein said impurities comprises chlorides, said chlorides further defined as at least one of SixHyClz, GexHyClz, COCl2, MoO2Cl2, SOCl2, C12, HCl, CCl4, CHCl3, CH2Cl2, CHCl3, SiCl4, and TiCl4, where x, y and z are greater than 0 and can have any integer value.

32. The semiconductor grade DMAC material of claim 25, wherein said impurities comprises hydrides, said hydrides further defined as at least one of SixHy, GexHy, NH3, PH3, AsH3 and SbH3, where x and y are greater than 0 and can have any integer value.

33. The semiconductor grade DMAC material of claim 25, said semiconductor grade DMAC material maintained in a substantially hermetically sealed and passivated canister.

34. A method of filling a canister configured for delivery of semiconductor grade DMAC material having a purity of 99.9 mol % or higher, comprising the steps of:
providing the canister that is hermetically or substantially sealed;
outgassing an interior volume of the canister;
passivating interior walls of the canister to remove residual solvents, moisture, particles and/or other impurities adsorbed onto the interior walls; followed by
introducing a semiconductor grade DMAC material having a purity of 99.9 mol % or higher into the canister, whereby air ingress is excluded to maintain the purity of 99.9 mol % or higher.

35. The method of claim 34, further comprising pushing a liquid phase of the semiconductor grade DMAC material from a source vessel into the canister with assistance of a pusher gas.

36. The method of claim 34, further comprising establishing sufficient pressure differential between a source vessel of the semiconductor grade DMAC material and the canister to allow transfer of a vapor phase of the semiconductor grade DMAC material into the canister.

37. A semiconductor grade dimethylaluminum chloride (DMAC) material having a purity of 99.9 mol % or higher, said semiconductor grade DMAC material comprising impurities, said impurities comprising at least one of hydrocarbons, moisture, hydrides, chlorides, alkyl-aluminum compounds and corresponding chlorine derivatives, atmospheric gases selected from the group consisting of H2, O2, N2, Ar, CO2 and CO;
whereby an aggregate amount of said impurities is greater than 0 mol % and up to about 0.1 mol %, a balance being said DMAC material;
with the proviso that when the impurities comprises hydrocarbons, the hydrocarbons comprises one or more of CH4, C2H6, C2H4, C3H8, C3H6, C4H10, C5H12, C6H14, C7H16, or CxHy, where x is an integer and y=2x−2, 2x, or 2x+2;
with the proviso that when the impurities comprises hydrides, said hydrides comprises one or more of SixHy, GexHy, NH3, PH3, AsH3 and SbH3, where x and y are greater than 0 and can have any integer value;
with the proviso that when the impurities comprises chlorides, said chlorides comprises one or more of SixHyClz, GexHyClz, COCl2, MoO2Cl2, SOCl2, C12, HCl, CCl4, CHCl3, CH2Cl2, CHCl3, SiCl4, and TiCl4, where x, y and z are greater than 0 and can have any integer value;
with the proviso that when the impurities comprises alkyl-aluminum compounds and corresponding chlorine derivatives, said alkyl-aluminum compounds and corresponding chlorine derivatives comprises one or more of Al(CH3)3, CH3AlCl2 and (C2H5)xAlCly where x and y are greater than 0 and can have any integer value.

38. A method of using semiconductor grade dimethylaluminum chloride DMAC, comprising the step of:
providing a canister at least partially filled with a liquid phase of the semiconductor grade DMAC material;
withdrawing the liquid phase of the semiconductor grade DMAC material from the canister at a semiconductor grade purity of 99.9 mol % or higher;
directing the liquid phase of the semiconductor grade DMAC material to an intermediate buffer vessel;
accumulating a sufficient amount of the DMAC material into the intermediate buffer vessel until a stable flow of DMAC vapor from the intermediate buffer vessel can occur;
dispensing the DMAC vapor from the intermediate vessel to a downstream tool for atomic layer etching in connection with a semiconductor fabrication process, said DMAC vapor being introduced into the downstream tool at the semiconductor grade purity of 99.9 mol % or higher.

39. A semiconductor grade dimethylaluminum chloride (DMAC) source material suitable for use in an improved aluminum ion implant process, said DMAC source material having a purity of at least about 99 mol % or greater based on total moles in the DMAC source material with reduced levels of impurities therein capable of generating C2H3 ions;
said impurities therein capable of generating C2H3 ions comprising at least one or more of the following: (i) hydrocarbons represented by the general formula of CxHy, with x equal to 2 and y equal to any integer satisfying valency rules for saturated, unsaturated, cyclic, aromatic and other hydrocarbon compounds; (ii) halogen derivatives of hydrocarbons represented by the general formula CxHyHalz, with x equal to 2 and “Hal” being either Cl, F, Br or I; (iii) alkyl or alkoxy halides or hydrides of aluminum including (C2H5)x(CH3)yAlClz, where x, y, or z=0 to 3, and x+y+z=3; (C2H5)3A1; (C2H5)2AlCl; (C2H5)AlCl2; (C2H5)2(CH3)Al; (C2H5)(CH3)2A1; and (C2H5)(CH3)AlCl; and their dimers and trimers; (iv) alkyl or alkoxy halides or hydrides of silicon including (C2H5)x(CH3)y4SiClz, where x, y, or z=0 to 4, x+y+z=4; (C2H5)4Si; (C2H5)3SiCl; (C2H5)2SiCl2; (C2H5)SiCl3; (C2H5)(CH3)3Si; (C2H5)(CH3)2SiCl; and(C2H5)(CH3)SiCl2; and (v) alkyl, alkylidene, alkoxy functionalities including ethyl (H3C-CH2-), vinyl (H2C═CH—), ethoxy (H3C-CH2-O—);
whereby an aggregate amount of said impurities therein capable of generating C2H3 ions is greater than 0 mol % and less than about 1 mol %, with a balance being said semiconductor grade DMAC material.

40. The semiconductor grade dimethylaluminum chloride (DMAC) source material of claim 39, whereby the aggregate amount of said impurities therein capable of generating C2H3 ions is greater than 0 mol % and less than about 0.1 mol %, with the balance being said semiconductor grade DMAC source material.

41. The semiconductor grade dimethylaluminum chloride (DMAC) source material of claim 39, whereby the aggregate amount of said impurities therein capable of generating C2H3 ions is greater than 0 mol % and less than about 0.01 mol %, with the balance being said semiconductor grade DMAC material.

42. A semiconductor grade dimethylaluminum chloride (DMAC) source material suitable for use in an improved aluminum ion implant process, said DMAC source material having a purity of at least about 99 mol % or higher, said semiconductor grade DMAC source material comprising reduced levels of one or more impurities therein capable of generating C2H3 ions,
whereby an aggregate amount of said one or more impurities therein capable of generating C2H3 ions is greater than 0 mol % and up to about 1 mol %, with a balance being said semiconductor grade DMAC material.

43. An improved method for performing aluminum ion implantation, comprising the steps of:
withdrawing high purity DMAC source material in a vapor phase from a storage and delivery package, said DMAC source material in the vapor phase having a purity of at least about 99 mol % or higher, said semiconductor grade DMAC source material comprising reduced levels of one or more impurities therein capable of generating C2H3 ions in an amount greater than 0 mol % and up to about 1 mol %;
flowing the high purity DMAC source material in the vapor phase without a co-flow gas configured to scavenge said C2H3 ions;
introducing said high purity DMAC source material into an ion source chamber.

44. The improved method of claim 43, further comprising:
ionizing said high purity DMAC source material without substantial production of said C2H3 ions from the one or more impurities contained in the high purity DMAC source material;
generating aluminum ions; and
implanting said aluminum ions into a wafer device; wherein said implanted aluminum ions are not contaminated with said C2H3 ions.
